(19) United States
(12) Patent Application Publication
(10) Pub. No.: US 2003/0107052 A1
(43) Pub. Date: Jun. 12, 2003

(54) Structure and method for fabricating a semiconductor device

(76) Inventors: Kwang-Yang Chan, Hsinchu (TW); Mu-Yi Liu, Taichung (TW); Tso-Hung Fan, Taipei Hsien (TW); Yen-Hung Yeh, Taoyuan Hsien (TW); Tao-Cheng Lu, Kaoshiung (TW)

Correspondence Address: J.C. Patents, Inc., Suite 250, 4 Venture, Irvine, CA, 92618, US

(21) Appl. No.: 10/047,719

(22) Filed: Jan. 14, 2002

(30) Foreign Application Priority Data
Dec. 10, 2001 (TW) 90130501

(51) Int. Cl. H01L 31/0328

(52) U.S. Cl. 257/200

(57) ABSTRACT

A method for manufacturing a semiconductor device. A trench is formed in a substrate. An insulation spacer is then formed on the sidewall of the trench. A first epitaxial silicon layer is formed in the trench, followed by doping the first epitaxial layer as a doped source/drain (S/D) region. A second epitaxial silicon layer is formed on the substrate and on the first epitaxial silicon layer, followed by forming a gate on the second epitaxial silicon layer. Then using the gate as a mask, ions are implanted to form an extended doped region. Thereafter, a rapid thermal annealing is performed to convert both the source/drain doped region and the extended doped region to a source/drain region.

### CROSS-REFERENCE TO RELATED APPLICATION

This application claims the priority benefit of Taiwan application serial no. 90130501, filed Dec. 10, 2001.

### BACKGROUND OF THE INVENTION

1. Field of the Invention

The present invention relates to a structure of a semiconductor device and a fabrication method thereof. More particularly, the present invention relates to a structure and a fabrication method of a semiconductor device, wherein an insulation spacer is placed at a source/drain junction under the channel.

2. Background of the Invention

To improve the integration of a device in the current trend of semiconductor manufacturing, the device is miniaturized according to the design rule. The channel length of the floating gate thus reduces correspondingly. The depletion regions generated from the S/D region, however, cause the channel length to reduce further. Moreover, the depletion regions of the source region and the drain region even overlap with each other to induce the short channel effect and the punch-through leakage problem.

For solving the aforementioned short channel effect and the punch-through leakage problem, the lightly doped drain junction of the memory device must correspondingly be more shallow. A shallower lightly doped drain junction can improve the short channel effect. For a memory device that uses the diffusion layer as the bit line, a shallower lightly doped drain junction, however, the resistance of the bit lit that is in contact with the source/drain (S/D) region would increase correspondingly, leading to a voltage drop at the serial resistor of the bit line. When the bit line is used to supply the voltage to S/D regions, the actual voltage drop between the source region and the drain region is reduced because the voltage drop is resulted from the serial resistor. A serious loading effect is thereby resulted due to a lowering of the current flow through the memory device. Furthermore, a shallower lightly doped drain junction easily brings about a junction current leakage problem because the distance between the metal silicide on the drain region and the lightly doped drain junction is reduced.

Other method for preventing the short channel effect includes performing super steep retrograde (SSR) channel doping or the pocket ion implantation. However, after a device is being miniaturized, the dopant concentration for both the SSR doping and the pocket ion implantation must be increased, which also easily bring about the junction leakage problem.

### SUMMARY OF THE INVENTION

Accordingly, the present invention provides a structure and a fabrication method for a semiconductor device, wherein the short channel effect, the drain induce barrier lowering (DIBL), the punch-through and junction leakage problems are prevented.

This invention also provides a structure of a semiconductor device and a manufacturing method thereof, wherein a deeper S/D junction and a thicker layer of metal silicide are formed to lower the resistance.

This invention provides a structure of a semiconductor device comprising at least a substrate, a S/D region, a gate structure, a channel region and an insulation spacer. The S/D region is formed in the substrate. A gate structure is formed on the surface of the substrate between the S/D region, wherein the gate structure extends to cover a part of the S/D region. A channel is positioned under the gate structure in the substrate. An insulation spacer is formed under the channel region and at the junction between the S/D region and the substrate. Moreover, the gate length is greater than the distance between the source region and the drain region at the top of the insulation spacer.

This invention provides a manufacturing method for a semiconductor devise. The method includes forming a trench in a substrate, and forming an insulation spacer on the sidewall of the trench. A first epitaxial silicon layer is selectively formed in the trench, followed by forming a S/D doped region in the first epitaxial layer. A second epitaxial silicon layer is formed on the first epitaxial layer, followed by forming a gate dielectric layer and a gate on the second epitaxial layer. Thereafter, using the gate as a mask, an ion implantation is conducted to form an extended doped region in the second epitaxial silicon layer. A rapid thermal annealing is then conducted to convert the S/D doped region and the extended doped region to a source/drain region.

Based on the foregoing, according to the present invention, an insulation spacer is formed at the junction between the S/D region and the substrate. Due to presence of the insulation spacer, the depletion regions of the the source region and the drain region are prevented from approaching each other. The problems of the short channel effect, the drain induced barrier lowering (DIBL) and the punch-through leakage are thus obviated.

Moreover, due to the shielding of the insulation spacer at the junction between the substrate and the S/D regions, deeper S/D regions can form to lower the sheet resistance of the source/drain regions.

Additionally, because a deeper source/drain region is formed according to the present invention, a thick metal silicide layer can be formed.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A to 1I are schematic, cross-sectional views showing the successive steps in fabricating a semiconductor device according to a preferred embodiment of the present invention.

### DESCRIPTION OF THE PREFERRED EMBODIMENTS

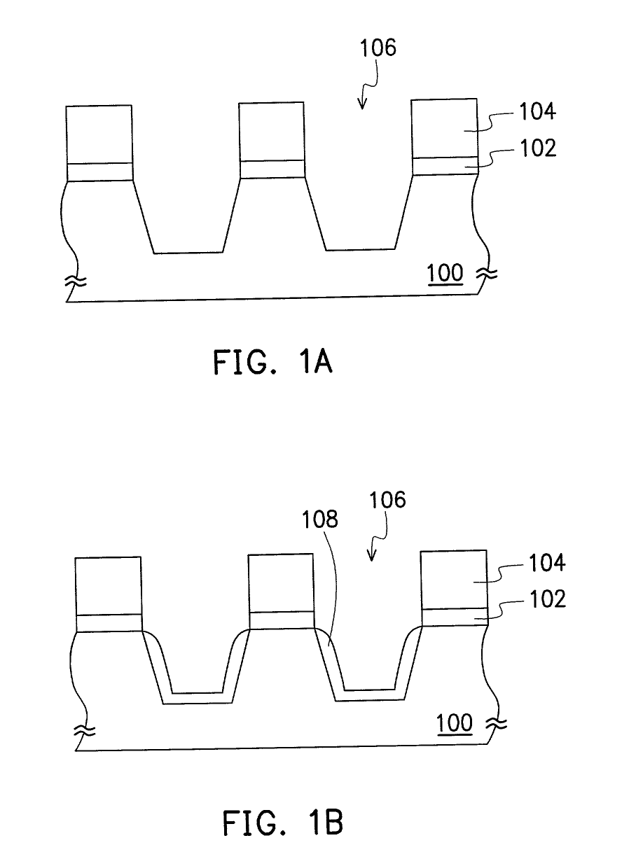

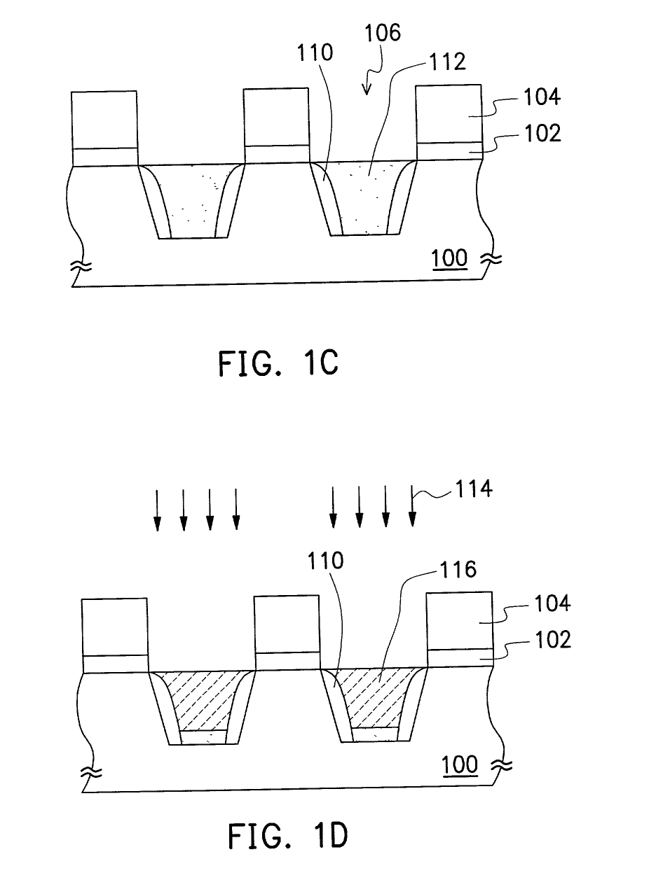

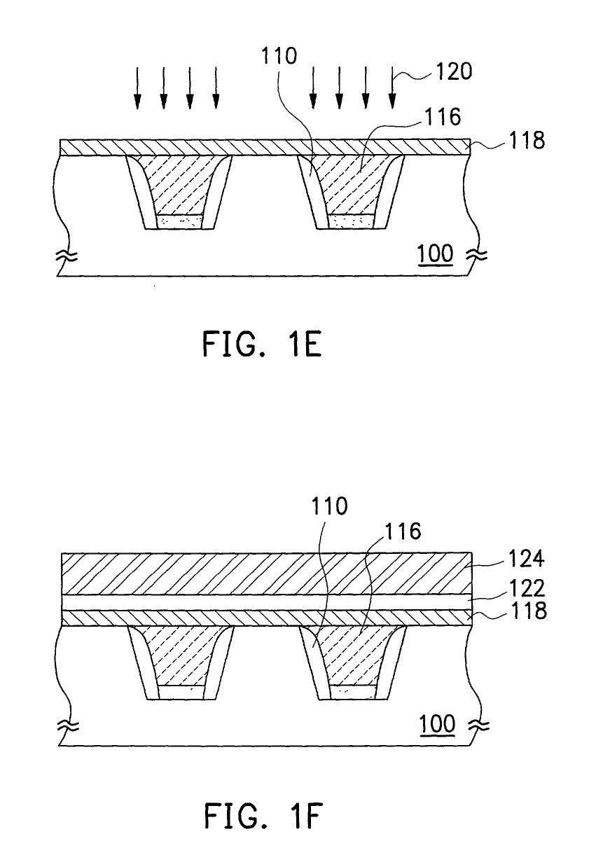

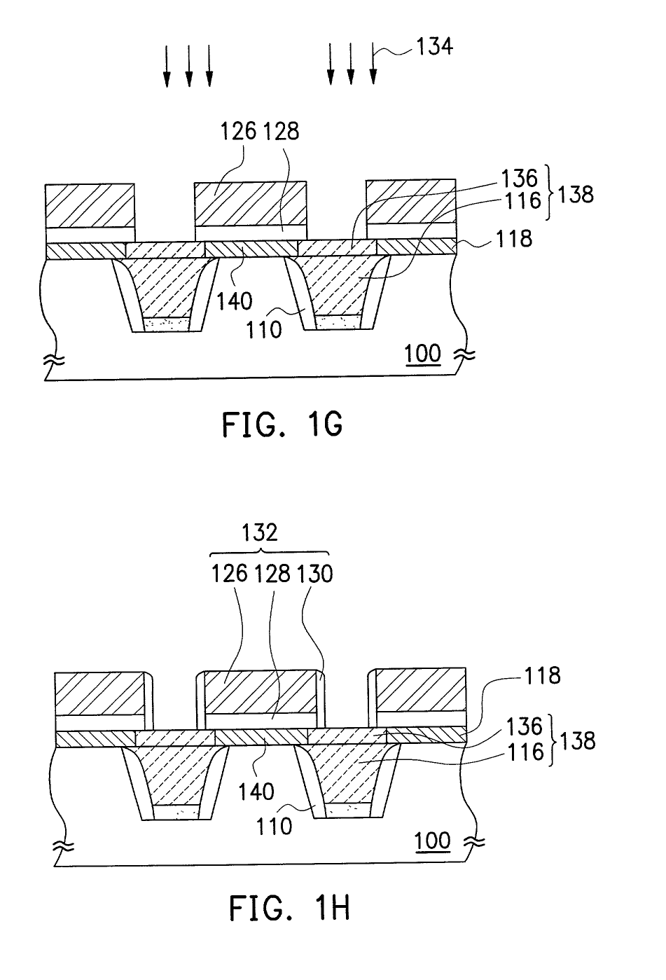

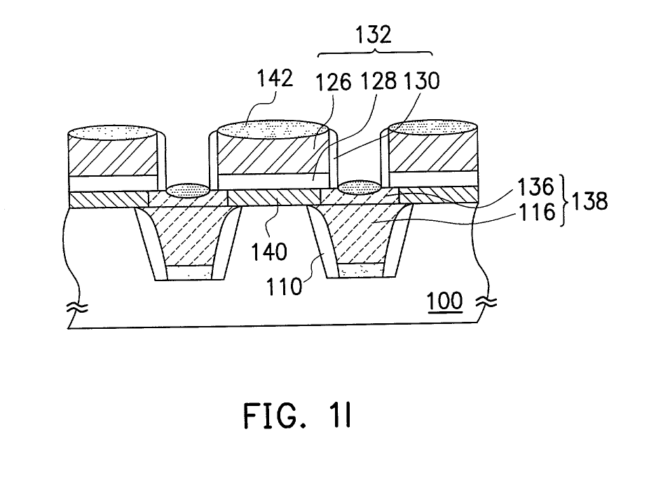

FIGS. 1A to 1I are schematic, cross-sectional views showing the successive steps in fabricating a semiconductor device according to a preferred embodiment of the present invention.

Referring to FIG. 1A, a substrate 100 is provided. A pad oxide layer 102 and a mask layer 104 on the pad oxide layer 102 are already formed on the substrate 100, and a trench 106 is formed in the substrate 100. The pad oxide layer 102, such as a silicon oxide layer, is formed by, for example, thermal oxidation. The mask layer 104, such as, a silicon nitride layer, is formed by, for example, chemical vapor deposition. The trench 106 is formed by, for example, forming a patterned photo-resist layer (not shown in Figure) on the mask layer 104. Using the photo-resist layer as a mask, anisotropic etching is conducted to remove portions of the mask layer 104, the pad oxide layer 102 and the substrate 100 to form the trench 106 in the substrate 100, wherein the depth of trench 106, extending from the bottom of the trench 106 to the surface of the substrate 100 is about 0.1 micron.

Referring to FIG. 1B, an insulation layer 108 is formed along the sidewall and the bottom of the trench 106, wherein the insulation layer 108 includes silicon oxide formed by thermal oxidation.

Referring to FIG. 1C, a portion of the insulation layer 108 is removed to form an insulation spacer 110 on the sidewall of the trench 106. Removing the portion of the insulation layer 108 is accomplished by the method of, for example, anisotropic etching.

Thereafter, an epitaxial silicon layer 112 is formed in the trench 106. Forming the epitaxial silicon layer 112 in the trench 106 is by a selective epitaxial growth method using low pressure chemical vapor deposition (LPCVD).

Referring to FIG. 1D, an ion implantation process 114 is conducted on the substrate 100 to form a source/drain region 116 in the epitaxial silicon layer 112.

Referring to FIG. 1E, the mask layer 104 and the pad oxide layer 102 are completely removed. The mask layer 104 is removed by, for example, wet etching with hot phosphoric acid, and the pad oxide layer 102 is removed by wet etching with hydrofluoric acid.

Still referring to FIG. 1E, an epitaxial silicon layer 118 is formed on the substrate 100. The epitaxial silicon layer 118 is formed by, for example, a nonselective epitaxial growth method using low pressure chemical vapor deposition (LPCVD). The epitaxial layer 118 is about 200 angstroms thick. An ion implantation process 120 is further conducted to adjust the threshold voltage Vₜ of the subsequently formed device.

Referring to FIG. 1F, a dielectric layer 122, which includes silicon oxide, is formed on the epitaxial silicon layer 118, for example, by thermal oxidation. A conductive layer 124, including polysilicon, is formed on the dielectric layer 122 by chemical vapor deposition.

Referring to FIG. 1G, the conductive layer 124 and the dielectric layer 122 are then patterned to form a gate 126 and a gate dielectric layer 128 on the substrate 100. The gate 126 and the gate dielectric layer 128 are formed by, for example, forming a patterned photoresist layer (not shown) on the conductive layer 124. Further using the patterned photoresist layer as a mask, parts of the conductive layer 124 and the dielectric layer 122 are removed by anisotropic etching.

Still referring to FIG. 1G, using the gate 126 as a mask, an ion implantation process 134 is conducted to form an extended doped region 136 in the epitaxial silicon layer 118. A rapid thermal annealing (RTA) is further conducted to convert the source/drain doped region 116 and the extended doped region 136 to a source/drain region 138, wherein the extended doped region 136 at the epitaxial silicon layer 118 is extended to underneath both ends of the gate dielectric layer 128. Meanwhile, the epitaxial silicon layer 118 under the gate dielectric layer 128 and between the extended doped region 136 becomes a channel 140.

Referring to FIG. 1H, a spacer 130 is formed on the sidewalls of the gate 126 and the gate dielectric layer 128. The spacer 130, which includes silicon oxide, is formed by covering the gate 126 and the epitaxial silicon layer 118 with an oxide insulation layer (not shown), followed by anisotropic etching the oxide insulation layer to form the spacer 130. The gate 126, the gate dielectric layer 128 and the spacer 130 form a gate structure 132.

Referring to FIG. 1I, a self-aligned silicide layer 142 is formed on the surfaces of the gate 126 and the S/D region 138 to complete the fabrication of the semiconductor device. The self-aligned salicide layer 142 is formed by covering the substrate with a metal layer (not shown), followed by performing a rapid anneal process to allow the metal layer and the silicon on the surfaces of the gate 126 and the source/drain region 138 to react. The unreacted metal layer is then removed, followed by another rapid anneal process to form the self-aligned salicide layer 142.

The structure of the semiconductor device of the present invention, displayed in the FIG. 1I, at least includes the substrate 100, the S/D region 138, the gate structure 132, the channel region 140 and the insulation spacer 110.

The S/D region 138 is embedded in the substrate 100, and the self-aligned silicide layers 142 are formed on the surface of the S/D region 138 to reduce the sheet resistance.

The gate structure 132 includes the gate 126, the gate dielectric layer 128 and the spacer 130. The gate 126 is set between the S/D regions 138 and on the surface of the substrate 100, and is extended to cover a part of the source/drain region 138. Additionally, a self-aligned silicide layer 142 is formed on the surface of the gate 126 to reduce the sheet resistance.

The gate dielectric layer 128 is formed between the substrate 100 and the gate 126, and the spacer 130 is formed on the sidewalls of the gate 126 and the gate dielectric layer 128.

The channel region 140 is located in the substrate 100 under the gate dielectric layer 128 and between the S/D regions 138. The insulation spacer 110 is located at the junction between the substrate and the source/drain region under the channel 140. According to the aforementioned structure, the gate length is greater than the distance between the source/drain regions 138 at the top of the insulation spacer 110.

Although in the above preferred embodiment, the present invention has been described a gate structure for a metal oxide semiconductor transistor (MOS), the present invention is applicable also to a gate structure for a read-only memory that includes a tunnel oxide layer, a floating gate, a dielectric layer and a silicon dioxide layer, or a gate structure for a nitride read-only memory that comprises a silicon oxide-silicon nitride-silicon oxide layer and a control gate, or a gate structure of a memory device that comprises a source/drain region.

Accordingly, an insulation spacer is formed at the junction between the S/D regions and the substrate. The insulation spacer prevents a most likely current leakage route between the source/drain regions. The problems of the short channel effect, the drain induced barrier lowering (DIBL) and the punch-through leakage are thus avoided when the device dimensions are being reduced

Moreover, with the shielding of the insulation spacer formed at the junction between the source/drain regions and the substrate, a formation of a deeper source/drain region is allowed to further lower the sheet resistance of the source/drain region.

Additionally, because a deeper source/drain region is formed according to the present invention, a thick metal silicide layer can be formed.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A structure of a semiconductor device, comprising:
a substrate;
a source/drain (S/D) region in the substrate;
a gate structure on the substrate between the S/D region which is also extended to cover a part of the S/D region;
a channel region under the gate structure in the substrate; and
an insulation spacer under the channel region and at a junction between the substrate and the source/drain region.

2. The structure of the semiconductor device of claim 1, wherein the gate structure comprises a gate, a gate dielectric layer and a spacer.

3. The structure of the semiconductor device of claim 1, wherein a gate length is greater than a distance between the source region and the drain region at a top of the insulation spacer

4. The structure of the semiconductor device of claim 3, wherein the gate dielectric layer is located between the gate and the substrate, and is extended to cover a part of the S/D region.

5. The structure of the semiconductor device of claim 1, further includes salicide layers on the gate structure and the source/drain region.

6. The structure of the semiconductor device of claim 1, wherein the insulation spacer includes at least silicon oxide.

7. The structure of the semiconductor device of claim 1, wherein the channel region is isolated from the gate structure by the insulation spacer to prevent a contact between the insulation spacer and the gate structure.

8. A method of manufacturing a semiconductor device, comprising:
forming a trench in a substrate;
forming an insulation spacer on a sidewall of the trench.
forming a first epitaxial silicon layer in the trench;
forming a source/drain (S/D) doped region in the first epitaxial silicon layer;
forming a second epitaxial silicon layer on the substrate and the first epitaxial silicon layer;
forming a gate on the second epitaxial silicon layer;
implanting ions to form an extended doped region in the second epitaxial silicon layer using the gate as a mask; and
forming a S/D region from the S/D doped region and the extended doped region by performing a rapid thermal annealing process;

9. The method of manufacturing the semiconductor device of claim 8, wherein the insulation spacer includes at least silicon oxide.

10. The method of manufacturing the semiconductor device of claim 8, wherein forming the insulation spacer further comprises:
forming an insulation layer in the trench; and
etching back the insulation layer to form the insulation spacer.

11. The method of manufacturing the semiconductor device of claim 10, wherein the insulation layer is formed by thermal oxidation.

12. The method of manufacturing the semiconductor device of claim 8, wherein forming the first epitaxial silicon layer includes using low pressure chemical vapor deposition (LPCVD) to perform a selective epitaxial growth method.

13. The method of manufacturing the semiconductor device of claim 8, wherein forming the second epitaxial layer includes using low pressure chemical vapor deposition (LPCVD) to perform selective epitaxial growth method.

14. The method of manufacturing the semiconductor device of claim 8, wherein a threshold voltage adjustment implantation process is conducted after forming the second epitaxial silicon layer.

15. The method of manufacturing the semiconductor device of claim 8, wherein a channel region is formed in the second epitaxial silicon layer under the gate structure and between the source/drain region.

16. The method of claim 15, wherein a gate length is greater than a distance between the source region and the drain region near a top of the spacer.

17. The method of manufacturing the semiconductor device of claim 8, wherein a salicide layer is further formed on surfaces of the gate and the S/D region.
